(19) United States
(12) Patent Application Publication
(10) Pub. No.: US 2023/0011559 A1
(43) Pub. Date: Jan. 12, 2023

(54) ELECTRIC DRIVE DEVICE AND ELECTRIC STEERING DEVICE

(71) Applicant: HITACHI ASTEMO, LTD., Hitachinaka-shi, Ibaraki (JP)

(72) Inventors: Narutoshi YAMADA, Hitachinaka-shi, Ibaraki (JP); Takuro KANAZAWA, Hitachinaka-shi, Ibaraki (JP); Kazuhiko NAKANO, Hitachinaka-shi, Ibaraki (JP); Akira ISHII, Hitachinaka-shi, Ibaraki (JP)

(73) Assignee: HITACHI ASTEMO, LTD., Hitachinaka-shi, Ibaraki (JP)

(21) Appl. No.: 17/783,211

(22) PCT Filed: Dec. 7, 2020
(86) PCT No.: PCT/JP2020/045372

§ 371 Date: Jun. 7, 2022

(30) Foreign Application Priority Data
Dec. 10, 2019 (JP) 2019-222728

(51) Int. Cl. H02K 9/22; H02K 5/04; H02K 11/30; B62D 5/04

(52) U.S. Cl. CPC H02K 9/22; H02K 5/04; H02K 11/30; B62D 5/0409

(57) ABSTRACT

Provided are an electronic drive device and an electronic steering device, in each of which: a mounting substrate has one surface as a first surface on which a first heat generating component is mounted and the other surface as a second surface on which a second heat generating component is mounted; a first heat dissipation member is arranged in contact with the second surface at a position corresponding to a mounted position of the first heat generating component such that heat generated by the first heat generating component is dissipated to a motor housing; and a second heat dissipation member is arranged in contact with the first surface at a position corresponding to a mounted position of the second heat generating component such that heat generated by the second heat generating component is dissipated to a cover.

### FIELD OF THE INVENTION

The present invention relates to an electric drive device and an electric steering device and, more particularly, to an electronic drive device and an electric steering drive each of which has integrated therein an electronic controller.

### BACKGROUND ART

In the general industrial machinery field, it is common to drive a mechanical control element by an electric motor. Recently, there has come into use a so-called mechanically and electrically integrated type electric drive device in which an electronic controller having a semiconductor element etc. is integrally mounted to an electric motor so that a rotation speed and rotation torque of the electric motor is controlled by the electronic controller.

As an example of such a mechanically and electrically integrated type electric drive device and as an example of an electric steering device, an electric power steering device for a vehicle is configured to detect the direction and torque of rotation of a steering shaft caused by driver's steering wheel operation, and then, drive an electric motor based on the detection results such that the electric motor rotates in the same direction as the rotation direction of the steering shaft so as to exert a steering assist torque. In this power steering device, an electronic controller is provided to control the electric motor.

In the electric power steering device in which the electronic controller is integrated, electronic components such as MOSFET for driving and control of the electric motor and electrical components such as power circuit capacitor are used. These electronic and electrical components include heat generating components whose heat generation amount is large. Furthermore, there is a tendency that the electronic components themselves are downsized and thereby reduced in heat dissipation area. It has thus been demanded to improve the performance of heat dissipation from the electronic and electrical components.

An electric power steering device with improved performance of heat dissipation from heat generating components is disclosed in Japanese Laid-Open Patent

For improvement of heat dissipation performance, the electronic power steering device shown in FIG. 6 of Patent Document 1 has a power board fixed to a heat sink member and a control circuit board mounting thereon heat generating components in contact with a metal cover.

### PRIOR ART DOCUMENTS

### Patent Document

Patent Document 1: Japanese Laid-Open Patent Publication No. 2013-147050

### SUMMARY OF THE INVENTION

### Problem to Be Solved by the Invention

In the electric power steering device as disclosed in Patent Document 1, the exterior surface area for the electronic components including the heat generating components, that is, the heat dissipation area for the heat generating components is decreased as the metal cover is fixed in close contact with the heat generating components. This can result in a deterioration of heat dissipation performance.

It is accordingly an object of the present invention to provide an electric drive device and an electric steering device each having improved performance of heat dissipation from heat generating components.

### Means for Solving the Problems

The present invention is directed to an electric drive device and an electric steering device, each of which is characterized in that an electronic controller comprises:

a mounting substrate having one surface defined as a first surface and the other surface defined as a second surface and mounting thereon control components, the control components including a first heat generating component having a heat generating attribute and mounted on the first surface and a second heat generating component having a heat generating attribute and mounted on the second surface;

a first heat dissipation member for dissipating heat generated by the first heat generating component mounted on the first surface, wherein the first heat dissipation member is in contact with the second surface at a position corresponding to a mounted position of the first heat generating component such that the heat generated by the first heat generating component is dissipated to a motor housing through the first heat dissipation member; and

a second heat dissipation member for dissipating heat generated by the second heat generating component mounted on the second surface, wherein the second heat dissipation member is in contact with the first surface at a position corresponding to a mounted position of the second heat generating component such that the heat generated by the second heat generating component is dissipated to a cover through the second heat dissipation member.

### Effects of the Invention

According to the present invention, heat generated by the heat generating components is dissipated from the mounting substrate to the casing members such as motor housing and cover through the heat dissipation members. More specifically, heat generated by the heat generating components is diffused through the substrate and transferred from the substrate to the first and second heat dissipation members. The electronic controller attains an increased contact area of the substrate with the first and second heat dissipation members, i.e., increased heat dissipation area and thereby achieves improved heat dissipation performance.

### BRIEF DESCRIPTION OF DRAWINGS

FIG. 1 is an overall perspective view of steering equipment as an example of application of the present invention.

FIG. 2 is a vertical cross-sectional view of an electric power steering device according to one embodiment of the present invention.

FIG. 3 is a first exploded perspective view of the electric power steering device of FIG. 2.

FIG. 4 is a second exploded perspective view of the electric power steering device of FIG. 2.

FIG. 5 is a top view of a mounting substrate of the electric power steering device as viewed from the cover side of FIG. 4.

FIG. 6 is a cross-sectional view of the vicinity of the mounting substrate as an illustration for explaining a positional relationship of the mounting substrate and heat dissipation members.

### DESCRIPTION OF EMBODIMENTS

Hereinafter, one embodiment of the present invention will be described in detail below with reference to the drawings. It is however to be understood that the present invention is not limited to the following embodiment. Various modification examples and application examples can be made based on the technical concept of the present invention. Those modification examples and application examples are included in the scope of the present invention.

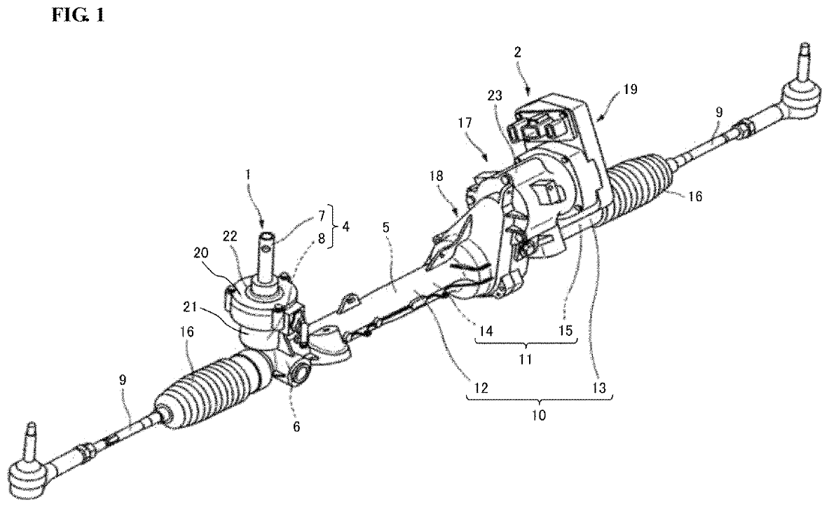

Before addressing one embodiment of the present invention, the configuration of steering equipment as an example of application of the present invention will be briefly described below with reference to FIG. 1.

FIG. 1 shows an electric power steering device of the type configured to, in addition to driving of a steered shaft caused by rotation of a steering shaft in accordance with steering wheel operation, detect a rotation angle, rotation direction and rotation torque of the steering shaft, rotate an electric motor based on these detection signals and assist a steering force by driving the steered shaft through transmission of the rotation of the electric motor to a nut in which the steered shaft is disposed.

As shown in FIG. 1, a steering system 1 of the electric power steering device includes: a steering shaft 4 connected to a steering wheel (not shown) which is arranged in a driver's room of a vehicle; a rack bar 5 as a steered shaft coupled to steerable vehicle wheels; and a conversion mechanism 6 for linking the steering shaft 4 and the rack bar 5. The conversion mechanism 6 is a so-called rack-and-pinion mechanism comprised of pinion teeth (not shown) formed on a tip end side of the steering shaft 4 and rack teeth (not shown) formed on an outer circumference of the rack bar 5.

Although the rack bar 5 is used as the steered member, a pitman arm is usable as the steered member instead of the rack bar 5. The steered member is not limited to these examples. The steered member may have a link mechanism between a steering actuator and the steerable vehicle wheels.

The steering shaft 4 has: an input shaft member 7 connected at one axial end thereof to the steering wheel so as to be integrally rotatable with the steering wheel; and an output shaft member 8 connected at one axial end thereof to the other axial end of the input shaft member 7 via a torsion bar (not shown). The rack bar 5 is connected at both axial end portions thereof to the pair of steerable vehicle wheels via tie rods 9 and knuckle arms, respectively. When the rack bar 5 is moved in its axial direction, the knuckle arms are respectively pulled via the tie rods 9 to change the direction of the steerable vehicle wheels.

A shock absorber assembly is fitted to inner circumferential surfaces of both cylindrical end portions of a rack housing 10 so as to surround the rack bar 5 from the outer circumferential side. The shock absorber assembly has a shock absorber made of a rubber or resin material. When the rack bar 5 is moved to its stroke end position, a joint portion of the rack bar 5 is brought at an end face thereof into contact with the shock absorber of the shock absorber assembly so that the shock absorber is deformed to perform a shock absorbing function. This shock absorber assembly is a well-known mechanism.

The rack housing 10 as a constituent part of a housing 3 is substantially cylindrical in shape. The rack bar 5 is axially movably accommodated in a rack bar accommodation portion 11 of the rack housing 10, with both of the axial end portions of the rack bar 5 being exposed to the outside. In this illustrated example, the rack housing 10 is formed with two axially separable member by casting a metal material. More specifically, the rack housing 10 has a first housing member 12 for accommodating therein one axial end side of the rack bar 5 and a second housing member 13 for accommodating therein the other axial end side of the rack bar 5. The first and second housing members are integrated into one by being joined together with a plurality of bolts.

The rack bar accommodation portion 11 has: a first rack bar accommodation section 14 extending through the first housing member 12 in the axial direction; and a second rack bar accommodation section 15 extending through the second housing member 13 in the axial direction. Bellows boots 16 are respectively disposed on both axial end portions of the rack housing 10 so as to be astride the tie rods 9. These boots 16 are made of an elastic material such as synthetic rubber to ensure a predetermined degree of flexibility and each functions to prevent the entry of water or dust into the housing 3.

A steering assist system 2 of the electric power steering device includes: an electric motor 17 as a drive unit for generating a steering assist force; a transmission mechanism 18 for transmitting a drive force of the electric motor 17 to the rack bar 5; various sensors for detecting various operating amounts of the power steering device; and a controller unit 19 (as an electronic controller unit) for driving and controlling the electric motor 17 based on output signals of the various sensors. Herein, the electric motor 17 and the transmission mechanism 18 constitute a steering actuator.

The electric motor 17 is a so-called three-phase alternating current motor driven by three-phase alternating current power. This electric motor has a motor housing 23 as a constituent part of the housing 3 and a motor element disposed in the motor housing 23.

The motor element has a plurality of coils respectively provided for independent drive systems so that the motor element can be driven by energizing the coil of at least one of the drive systems or the coils of all of the drive systems. In the present example, the motor element is provided with two coils corresponding to redundant first and second drive systems. The number of coils provided is not limited to two. Any number of coils can be provided corresponding to three or more drive systems.

It is feasible to drive the motor element by energizing the coils of all of the drive systems in a normal operating state. It is alternatively feasible to use the first drive system as a main drive system and the second drive system as a sub drive system so that the motor element is driven by energizing the coil of the first drive system in a normal operating state (with or without energization of the coil of the second drive system) and energizing the coil of the second drive system as a backup in the event of a failure occurring in the first drive system.

The various sensors include: a steering angle sensor that detects, as a steering angle, the amount of rotation of the steering wheel with respect to the neutral steering angle position; and a torque sensor that detects a torque inputted to the steering shaft 4. Both of the steering angle sensor and the torque sensor are accommodated in a housing 22 which is provided to surround an outer circumference of the steering shaft 4.

The housing 22, protecting the sensors, has a sensor housing part 21 formed on the rack bar accommodation portion of the rack housing 10 and a sensor cover 20 fixed to the sensor housing part 21 by fixing bolts. The sensor cover 20 is formed into a disc shape from a plate material of predetermined thickness.

The steering angle sensor is accommodated in the housing 22 and is attached to an outer circumference of the input shaft member 7 of the steering shaft 4 so as to detect the steering angle based on the amount of rotation of the input shaft member 7. In the present example, the steering angle sensor is redundantly configured with steering angle detection sections corresponding to the first and second drive systems such that each of the steering angle detection sections detects the steering angle.

The torque sensor is also accommodated in the housing 22 and is disposed astride the input shaft member 7 and the output shaft member 8 so as to detect the steering torque based on the amount of displacement between the relative rotational positions of the input and output shaft members 7 and 8.

Further, the torque sensor is configured with torque detection sections corresponding to the first and second drive systems such that the each of the torque detection sections detects the steering torque. The steering angle sensor and the torque sensor are electrically connected to the controller unit 19 via a harness (not shown) which is disposed along an outer circumference of the rack housing 10

Each of the steering angle sensor and the torque sensor may be redundantly configured with main and sub detection sections. In this case, the detection results of the main detection sections of the steering angle sensor and the torque sensor are used for drive control of the electric motor in a normal operating state; and, in the event of anomalies occurring in the main detection sections such as sensor elements or signal lines of the steering angle sensor and the torque sensor, the detection results of the sub detection sections of the steering angle sensor and the torque sensor are used for drive control of the electric motor.

In the electric power steering device, when the steering shaft 4 is rotated in either direction by steering wheel operation, the torque sensor detects the rotation direction and rotation torque of the steering shaft 4. Then, the controller unit 19 determines the driving operation amount of the electric motor 17 based on these detection results.

The controller unit 19 causes a power switching element to drive the electric motor 17 according to the determined driving operation amount so that an output shaft of the electric motor 17 rotates to drive the steering shaft 4 in the same direction as the operation direction of the steering wheel. The rotation of the motor output shaft is transmitted to the nut through input and output pulleys. With the rotation of the nut, the rack bar is driven to steer the vehicle.

In this example, the controller unit has a first electronic control section EC1 (first drive system) and a second electronic control section EC2 (second drive system) such that each of the first electronic control section EC1 (first drive system) and the second electronic control section EC2 (second drive system) determines the driving operation amount of the electric motor 17 and causes its power switching element to the electric motor 17 according to the determined driving operation amount.

The first electronic control section EC1 (first drive system) and the second electronic control section EC2 (second drive system) may share motor drive load at equal rates so as to drive the motor output at 100% by respectively outputting 50% operation load. It is alternatively feasible to, assuming the output required of the motor as 100%, set the load sharing rate of one electronic control section larger than the load sharing rate of the other electronic control section (e.g. set the load sharing rate of one electronic control section to 60% and set the load sharing rate of the other electronic control section to 40%) rather than by setting the load sharing rate of the respective electronic control sections to 50%.

According to one embodiment of the present invention, the controller unit includes: a mounting substrate having one surface as a first surface that mounts thereon a first heat generating component (e.g. MOSFET) is mounted and the other surface as a second surface that mounts thereon a second heat generating component (e.g. capacitor); a first heat dissipation member that dissipates heat generated by the first heat generating component mounted on the first surface, wherein the first heat dissipation member is in contact with the second surface at a position corresponding to a mounted position of the first heat generating component so as to allow heat dissipation to the motor housing; and a second heat dissipation member that dissipates heat generated by the second heat generating component mounted on the second surface, wherein the second heat dissipation member is in contact with the first surface at a position corresponding to a mounted position of the second heat generating component so as to allow heat dissipation to the cover.

With such a configuration, heat of the heat generating components is dissipated from the mounting substrate to the casing members through the heat dissipation members by transferring the heat of the heat generating components through the substrate and then from the mounting substrate to the first and second heat dissipation members.

Since the heat is transferred through the mounting substrate so as to spread around the peripheries of the heat generating components, each of the first and second heat dissipation members obtains a greater area of contact with the mounting substrate than the mounted area of one heat generating component. This brings about an increase of heat dissipation area, which leads to an improvement of heat dissipation performance. Furthermore, any of the following effects can be obtained.

The heat of the first heat generating component mounted on the cover-side first surface is dissipated to the motor housing through the first heat dissipation member which is arranged in contact with the second surface opposite to the cover side; and the heat of the second heat generating component mounted on the second surface opposite to the cover side is dissipated to the cover through the second heat dissipation member which is arranged in contact with the cover-side first surface. This enables efficient dissipation of the heat of the heat generating components to the outside air.

Each of the contact between the second surface and the first heat dissipation member and the contact between the first surface and the second heat dissipation member can be in the form of either direct contact or indirect contact with an intermediate material applied between the second surface and the first heat dissipation member or between the first surface and the second heat dissipation member. Examples of the intermediate material include a heat dissipation sheet, a heat dissipation paste (such as heat dissipation grease or heat dissipation gel), a material for reducing a clearance at the contact area of the mounting substrate with the heat dissipation member, a material for improving heat transfer at the contact area of the mounting substrate with the heat dissipation member, and the like.

As such an intermediate material, a thermosetting resin material such as FIPG material and a curable resin material which hardens with time are applicable. An elastic material is also applicable as the intermediate material.

In the case where there are variations in the fixing dimension of the metal cover, the metal cover may be excessively brought into close contact with the heat generating component so as to cause damage on the heat generating component during the assembling process or may not be sufficiently brought into close contact with the heat generating component so as to cause loss of heat dissipation from the heat generating component.

In the present embodiment, however, the cover and the cover-side heat generating component are in a non-contact state. This makes it possible to prevent damage on the cover-side heat generating component. This also makes it possible to prevent stress load from being exerted on the heat generating component by thermal shrinkage of the metal cover due to the ambient temperature.

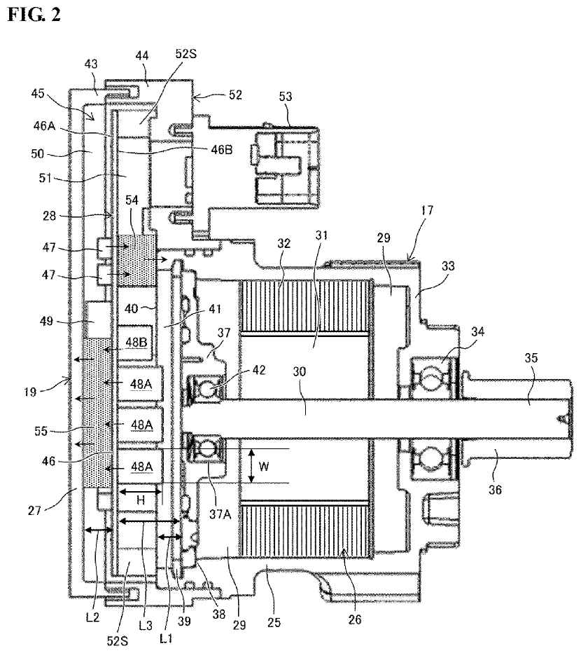

Hereinafter, the concrete configuration of the electric power steering device according to the present embodiment of the invention will be described below with reference to FIGS. 2 to 6.

As shown in FIGS. 2 to 4, the electric motor 17 constituting the electric power steering device includes: the motor housing 25 (as a second exterior member or second casing member) having high thermal conductivity, which is formed with a cylindrical portion from a metal material such as aluminum alloy; and the electric motor element 26 accommodated in the motor housing 25. The controller unit 19 as the electronic controller unit includes: the cover 27 (as a first exterior member or first casing member) having high thermal conductivity, which is formed of a metal material such as aluminum alloy and disposed on an end side of the motor housing 25 opposite to an output portion 35 of the rotation shaft 30 of the electric motor; and an electronic controller 28 covered by and accommodated in the cover 27. The cover 27 is hereinafter also referred to as the metal cover 27.

In the present embodiment, the cover 27 is made of a metal material as mentioned above. The cover 27 may alternatively be a cover made of a thermally conductive resin cover or be a resinous cover formed by insert molding such that a surface of the second heat dissipation member, which is made of a metal material, is partially exposed from the cover.

A highly thermally conductive controller case 52 (as a second exterior member), which is formed of a metal material such as aluminum alloy and defines a space for accommodating therein the electronic controller 28, is disposed between the metal cover 27 and the motor housing 25 as will be explained later in detail. The motor housing 25 is fixed to one end side of the controller case 52, whereas the metal cover 27 is fixed to the other end side of the controller case 52.

Consequently, the electronic controller 28 is accommodated and arranged in a space surrounded by an end part of the motor housing 25 (corresponding to the after-mentioned lateral wall part 37), the controller case 52 and the metal cover 27. The controller case 52 may be formed integral with the motor housing 25. In other words, the combination of the controller case 52 and the motor housing 25 may be defined as the motor housing 25 (as a second exterior member).

Since the controller case 52 is made of an aluminum alloy in the present embodiment, the controller case 52 also serves as a heat sink. Thus, the combination of the controller case 52 and the motor housing 25 leads to an increased heat capacity so as to receive a larger amount of heat. In the present embodiment, as will be explained later, the controller case 52 and the motor housing 25 are adapted to receive heat from control components such as MOSFET whose heat generation amount is large.

The metal cover 27 and the controller case 52 are integrally joined and fixed at respective opposed end surfaces thereof by an adhesive, welding or fixing bolts. In the present embodiment, the metal cover 27 and the controller case 52 are joined into one by an adhesive. The adhesive can be provided with a waterproof seal function. A thermosetting resin material etc. is applicable as the adhesive.

The motor housing 25 has formed therein an accommodation space 29 for accommodating the electric motor element 26. The electric motor element 26 basically include, in addition to the rotation shaft 30, a rotor 31 fixed to the rotation shaft 30 and a stator 32 located around the rotor 31. The motor housing 25 is provided in a bottomed cylindrical shape with a housing bottom portion 33. A ball bearing 34 is disposed in the center of the housing bottom portion so as to rotatably receive the rotation shaft 30.

The output pulley 36 is fixed to the output portion 35 of the rotation shaft 30 which protrudes from the housing bottom portion 33. A rubber belt (not shown) is wound around the output pulley 36. The input pulley is fixed to the nut which is screwed onto the rack bar. The rubber belt is also wound around the input pulley. This pulley-and-belt mechanism converts rotation of the rotation shaft 30 to forward or reverse rotation of the nut so as to move the rack bar for steering operation.

A lateral wall part 37 (corresponding to the end part of the motor housing), which serves as a lid for hermetically sealing the accommodation space 29 of the motor housing 25, is attached to the end side of the motor housing 25 opposite to the output portion 35 of the electric motor element 26. The lateral wall part 37 is engaged with an engagement step portion 38 of the motor housing 25, which is formed extending toward the output portion 35 along the axial direction of the motor housing, and is fixed in position and thereby prevented from slip-off by a clip 39. There is hence a space (opening) 41 of predetermined length (L1) defined between an open end 40 of the motor housing 25 and the lateral wall part 37 in the axial direction of the rotation shaft 30.

A bearing accommodation portion 34 is formed in the center of the lateral wall part 37. A ball bearing 42 is disposed in the bearing accommodation portion 34 coaxially with the ball bearing 34 so as to rotatably receive the rotation shaft 30. Thus, the rotation shaft 30 is rotatably supported by the ball bearings 34 and 42.

The motor housing 25 and the lateral wall part 37 are each made of an aluminum alloy and serve as heat sinks for dissipating heat generated by the electric motor element 26 and heat generated by the heat generating components of the after-mentioned power supply and conversion circuit components etc. to the outside air. The motor housing 25 and the lateral wall part 37 can also serve as heat masses for receiving the above-mentioned heat and thereby suppressing excessive temperature rises of the electric motor element 26 and the heat generating components.

Although the lateral wall part 37 is formed separately from the motor housing 25 so as to close the open end 40 of the motor housing 25 in the present embodiment, it is needless to say that the lateral wall part 37 can alternatively be formed integral with the motor housing 25. In such an alternative case, the bottom portion 33 is formed as a separate part.

An annular fitting groove is recessed in an open end portion 44 of the controller case 52 along the axial direction of the rotation shaft 30. A tip end of an open end portion 43 of the metal cover 27 is fitted in the fitting groove. An adhesive having a seal function is filled in the fitting groove so as to ensure fluid tightness between the controller case and the metal cover. The metal cover 27 has formed therein an accommodation space 45 for accommodating the electronic controller 28.

The electronic controller 28, accommodated in the accommodation space 45, include: a power supply circuit having a power IC element for providing a required power supply, a capacitor 48A for smoothing the power supply and a switching element capable of interrupting the power supply; a noise filter circuit having a capacitor 48B and a coil; a power conversion circuit having a power switching element 47 such as MOSFET or IGBT for driving and controlling the electric motor element 26 of the electric motor 17; a control circuit having a processing computer such as microcomputer for controlling the power switching element; a pre-driver circuit for converting an operation signal from the processing computer to a drive signal (gate signal) of the power conversion circuit; and a communication driver connected to an in-vehicle network such as CAN communication network so as to transmit and receive communication signals. An output terminal of the power switching element is electrically connected to a coil input terminal of the electrical motor via a busbar.

The electronic controller 28 has a structure in which electronic and electrical components as “control components” constituting the above-mentioned power supply circuit, power conversion circuit and control circuit are mounted on both surfaces of one mounting substrate 46. Examples of the mounting include resinous substrates such as glass-epoxy substrate. In FIG. 2, the main electronic and electrical components pertinent to the present embodiment are representatively illustrated. In the present embodiment, for example, the MOSFET 47 as the power switching element, the coil 49 and the like are mounted on the first surface 46A of the mounting substrate 46 facing the metal cover 27; and the capacitor 48A as the constituent component of the power supply circuit, the capacitor 48B as the constituent component of the noise filter circuit and the like are mounted on the second surface 46B of the mounting substrate 46 facing the electric motor element 26.

Herein, each of the MOSFET 47 and the capacitor 48A, 48B is large in heat generation amount and thus is treated as a “heat generating component” having a “heat generating attribute” in the present embodiment. The other electronic and electrical components, such as the coil 49, the microcomputer and its peripheral equipment as the constituent components of the control circuit and the like, are not so large in heat generation amount and thus are not treated as heat generating components. These other electronic and electrical components can alternatively be treated as heat generating components as needed.

A substrate placement step portion 52S is formed in the controller case 52. The mounting substrate 46 is placed on the substrate placement step portion 52S and thereby fixed in position in the rotation shaft direction. Depending on the length of the substrate placement step portion 52S, the accommodation space 45 is divided into two regions whereby a length (L2) of the first electrical/electronic component accommodation space region 50 in the rotation shaft direction and a length (L3) of the second electrical/electronic component accommodation space region 51 in the rotation shaft direction are determined. In the present embodiment, the mounting substrate 46 is fixed at a position slightly closer to the motor housing than the metal cover 27 side open end of the controller case 52.

The first electrical/electronic component accommodation space region 50 is provided between the mounting substrate 46 and the metal cover 27. The MOSFET 47 and the coil 49 etc. are disposed in the accommodation space region 50 and mounted on the first surface 46A of the mounting substrate 46. The second electrical/electronic component accommodation space region 51 is provided between the mounting substrate 46 and the lateral wall part 37. The capacitors 48A and 48B etc. are disposed in the accommodation space region 51 and mounted on the second surface 46B of the mounting substrate 46. Herein, the first surface 46A of the mounting substrate 46 is a mounting surface facing and opposed to the metal cover 27, whereas the second surface 46B of the mounting substrate 46 is a mounting surface facing and opposed to the lateral wall part 37.

The length (L2) of the first electrical/electronic component accommodation space region 50 between the metal cover 27 and the mounting substrate 46 in the rotation shaft direction and the length (L3) of the second electrical/electronic component accommodation space region 51 between the lateral wall part 37 and the mounting substrate 46 in the rotation shaft direction are set to satisfy a relationship of L2<L3. This leads to a reduction in the axial length (overall length) of the rotation shaft 30 of the electric power steering device.

More specifically, the ball bearing 42 is disposed on an electric motor element 26 side of the lateral wall part 37, which is fixed in the motor housing 25, at a position closer to the electric motor element 26 such that the ball bearing 42 does not protrude from a mounting substrate 46 side of the lateral wall part 37. Accordingly, the distance from the lateral wall part 37 side mounting surface (second surface 46B) of the mounting substrate 46 to the lateral wall part 37 is enlarged so that the second electrical/electronic component accommodation space region 51 is set large.

The so-called tall-type electronic and electrical components can be thus arranged in the large second electrical/electronic component accommodation space region 51. On the other hand, the distance from the metal cover 27 side mounting surface (first surface 46A) of the mounting board 46 to the metal cover 27 is shortened so that the first electrical/electronic component accommodation space region 50 is set smaller than the large second electrical/electronic component accommodation space region 51. The so-called short-type electronic and electrical components can be thus arranged in the small first electrical/electronic component accommodation space region 50.

In the present embodiment, the capacitors 48A and 48B correspond to the tall-type electronic or electrical components. The capacitors 48A and 48B are mounted on the lateral wall part 37 side mounting surface (second surface 46B) of the mounting substrate 46 as mentioned above. The MOSFET 47 and the coil 49 correspond to the short-type electronic or electrical components. The MOSFET 47 and the coil 49 are mounted on the metal cover 27 side mounting surface (first surface 46A) of the mounting substrate 46.

As one example of the definition of the tall- or short-type, the tall-type means that the vertical height (H) of the electronic or electrical component from the mounting surface is greater than the length (W) of the surface of the electronic or electrical component mounted on the mounting substrate (that is, the dimension of the electronic or electrical component in the width direction).

By way of example, the relationship of the length (W) of the surface of the capacitor 48A mounted on the mounting substrate and the vertical height (H) of the capacitor 48A from the mounting surface is shown in FIG. 2.

There is a case where part of the electronic components, such as capacitor, has its exterior formed in a cylindrical shape. In such a case, the outside diameter of the cylindrical exterior of the electronic component is determined as the length (W) of the surface of the electronic component mounted on the mounting substrate.

In the case where the electronic component such as microcomputer, MOSFET, driver element, IC element etc. is square or rectangular in exterior shape in plan view, the length of any one side of the exterior of the resin-packaged electronic component is determined as the length of the surface of the electronic component mounted on the mounting substrate.

In the present embodiment, the heat generating component mounted on the metal cover 27 side mounting surface (first surface 46A) of the mounting substrate 46 has a height from the mounting surface, which is smaller than the length (L2) of the first electrical/electronic component accommodation space region 50; and the heating generating component mounted on the lateral wall part 37 side mounting surface (second surface 46B) of the mounting substrate 46 has a height from the mounting surface, which is greater than the length (L2) of the first electrical/electronic component accommodation space region 50 and smaller than the length (L3) of the second electrical/electronic component accommodation space region 51.

As mentioned above, the axial overall length of the rotation shaft 30 of the electronic power steering device is shortened by setting the axial length of the first electrical/electronic component accommodation space region 50 and the axial length of the second electrical/electronic component accommodation space 51 to satisfy the relationship of “L2<L3” and then arranging the tall-type electronic and electrical components, which cannot be arranged in the first electrical/electronic component accommodation space region 50, in the second electrical/electronic component accommodation space region 51.

This is for the reason that the length (L3) of the second electrical/electronic component accommodation space region 51 is enlarged as the length (L1) defined between the open end 40 of the motor housing 25 and the lateral wall part 37 is shortened by bringing the lateral wall part 37 as close as possible to the electric motor element 26 with the utilization of the accommodation space 29 of the motor housing 26.

As one specific example, it is feasible to arrange the circuit with the relatively tall-type electronic component, such as noise filter circuit, power smoothing circuit etc., in the second electrical/electronic component accommodation space region 51 and arrange the circuit with the relatively short-type electronic component, such as processing circuit, vehicle network (CAN) communication circuit, power interruption circuit, power conversion circuit, power conversion circuit driver (pre-driver circuit) etc., in the first electrical/electronic component accommodation space region 50. Even in such an example, the axial overall length of the rotation shaft 30 of the electronic power steering device can be shortened.

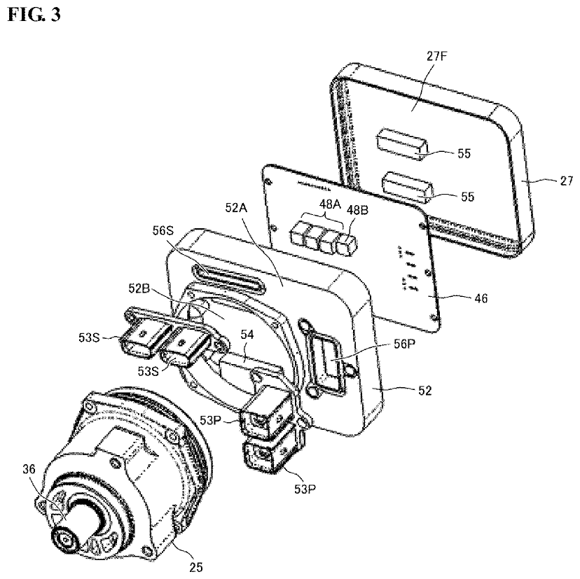

A opening 52B (see FIG. 3) is formed in a bottom wall portion 52A (see FIG. 3) of the controller case 52 facing the lateral wall part 37, at a position centering on the rotation shaft 30, so as to be open in the direction of the motor rotation shaft. The opening 52B is located to surround, from the outer circumferential side, the end part of the motor housing 25 to which the lateral wall part 37 is attached. Consequently, the space (opening) 41 and the accommodation space 45 are brought into communication with each other. Then, tip end sides of the capacitors 48A and 48B mounted on the second surface 46B of the mounting substrate 46 are situated within the space (opening) 41.

As mentioned above, at least part of the electronic components are mounted on the second surface 46B of the mounting substrate 46 at such positions that the tip end sides of these electronic components are situated within the region of the space (opening) 41. This makes it possible to, in the mounted state of the electronic components, situate the tip end sides of the electronic components within the space (opening) 41. Alternatively, the tip end sides of the electronic components may be situated within the motor housing 25.

Further, the arrangement position of the mounting substrate 46 in the axial direction of the rotation shaft 30 can be shifted toward the electric motor 17 side by situating the tip end sides of the electronic components within the space (opening) 41 or within part of the motor housing 25. This makes it possible to shorten the length (L3) of the second electrical/electronic component accommodation space region 51 while ensuring the height dimension of the electronic components, thereby allowing a reduction in the dimension of the electronic controller in the axial direction of the rotation shaft 30.

A connector terminal assembly 53 in which terminal members are partially resin-molded is disposed adjacent to the outer side of the controller case 52. This connector terminal assembly 53 extends in parallel with the rotation shaft 30 at a position beside an outer circumferential surface of the motor housing 25 along the axial direction of the rotation shaft 30.

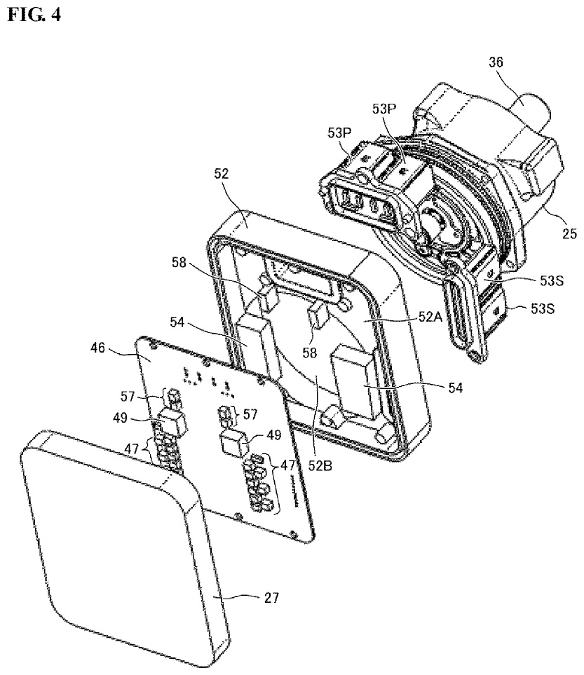

As shown in FIGS. 3 and 4, the connector terminal assembly 53 has two power supply terminal assembly parts 53P and two signal terminal assembly parts 53S. The reason for the connector terminal assembly having two power supply terminal assembly parts 53P and two signal terminal assembly parts 53S is that the electronic controller 28 is provided with a redundant system configuration (duplexed system configuration) as mentioned above.

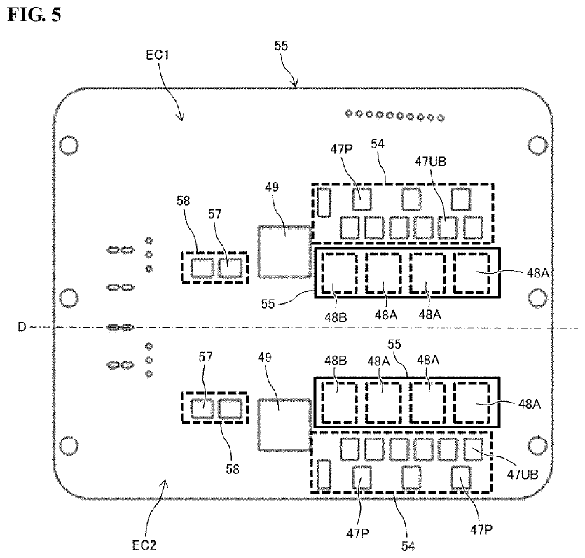

One of the power supply terminal assembly parts 53P and one of the signal terminal assembly parts 53S are electrically connected to the first electronic control section EC1 (see FIG. 5) for control of the first motor coil. The other power supply terminal assembly part 53P and signal terminal assembly part 53S are electrically connected to the second electronic control section EC2 (see FIG. 5) for control of the second motor coil. Each of the signal terminal assembly parts 53S is equipped with signal terminals for connection to the steering angle sensor and the torque sensor and signal terminals for communication with the vehicle network (CAN communication network). The redundant system on the mounting substrate 46 will be explained later.

As shown in FIGS. 2 to 4, the second heat dissipation member 55 is disposed on an inner wall surface 27F of the metal cover 27 facing the mounting substrate 46 (see FIG. 3). The second heat dissipation member 55 is made of a metal material such as aluminum alloy and is thermally coupled to the metal cover 27 by being welded to or formed integrally with the metal cover so as to allow heat dissipation to the metal cover 27. As shown in FIG. 2, the second heat dissipation member 55 is shaped to be in thermal contact with the metal cover 27 side mounting surface (first surface 46A) of the mounting substrate 46 in a state that the metal cover 27 is fixed to the controller case 52.

Similarly, the first heat dissipation member 54 is disposed on an inner surface of the controller case 52. The first heat dissipation member 54 is also made of a metal material such as aluminum alloy and is thermally coupled to the controller case 52 (see FIG. 4) by being welded to or formed integrally with the controller case. In a state that the controller case 52 is fixed to the motor housing 25, the first heat dissipation member 54 is in contact intimate contact with and thermally coupled to the open end 40 of the motor housing 25 so as to allow thermal dissipation to the motor housing 25. As shown in FIG. 2, the first heat dissipation member 54 is shaped to be in thermal contact with the lateral wall part 37 side mounting surface (second surface 46B) of the mounting substrate 46 in a state that the mounting substrate 46 is fixed to the controller case 52.

Next, the above explanation will be supplemented below with reference to FIGS. 3 and 4.

As shown in FIG. 3, the controller case 52 is formed with a power supply connector accommodation portion 56P and a signal connector accommodation portion 56S. The power supply terminal assembly parts 53P are fitted in the power supply connector accommodation portion 56P, whereas the signal terminal assembly parts 53S are fitted in the signal connector accommodation portion 56S. These two power supply terminal assembly parts 53P and two signal terminal assembly parts 53S are respectively connected to the electronic control sections of the redundant system on the mounting substrate 46.

The capacitors 48A and 48B as constituent components of the redundant system are mounted on the lateral wall part 37 side mounting surface (second surface 46B) of the mounting substrate 46 (in the figure, only the capacitors of one of the control sections are shown). Two second heat dissipation members 55 are disposed integrally on the inner wall surface 27F of the metal cover 27 in correspondence with these redundant system components. The second heat dissipation members 55 are located along the mounted positions of the capacitors 48A and 48B so that heat generated by the capacitors 48A and 48B is dissipated to the metal cover 27 through the mounting substrate 46 and the second heat dissipation members 55.

As shown in FIG. 4, the MOSFETs 47 and the coils 49 as constituent components of the redundant system are mounted on the metal cover 27 side mounting surface (first surface 46A) of the mounting substrate 46. Two first heat dissipation members 54 are disposed on the inner surface of the controller case 52 in correspondence with these redundant system components. The first heat dissipation members 54 are located along the mounted positions of the MOSFETs 47 so that heat generated by the MOSFETs 47 is dissipated to the controller case 52 and the motor housing 25 through the mounting substrate 46 and the first heat dissipation members 54.

Furthermore, MOSFETs 57 as constituent components of the power supply circuit are mounted on the metal cover 27 side mounting surface (first surface 46A) of the mounting substrate 46. Two third heat dissipation members 58 are disposed on the inner surface of the controller case 52 in correspondence with these circuit components. The third heat dissipation members 58 are also located along the mounted positions of the MOSFETs 57 so that heat generated by the MOSFETs 57 is dissipated to the controller case 52 and the motor housing 25 through the mounting substrate 46 and the third heat dissipation members 58.

The third heat dissipation member 58 is made of a metal material such as aluminum alloy as in the case of the first heat dissipation member 54 and is thermally coupled to the controller case 52 by being welded to or formed integrally with the controller case.

As mentioned above and as indicated by allows in FIG. 2, heat generated by the capacitors 48 is transferred to the metal cover 27 through the mounting substrate 46 and the second heat dissipation members 55 and then dissipated to the outside; and heat generated by the MOSFETs 47 and 58 is transferred to the controller case 52 and the motor housing 25 through the mounting substrate 46 and the first and third heat dissipation members 54 and 58 and then dissipated to the outside.

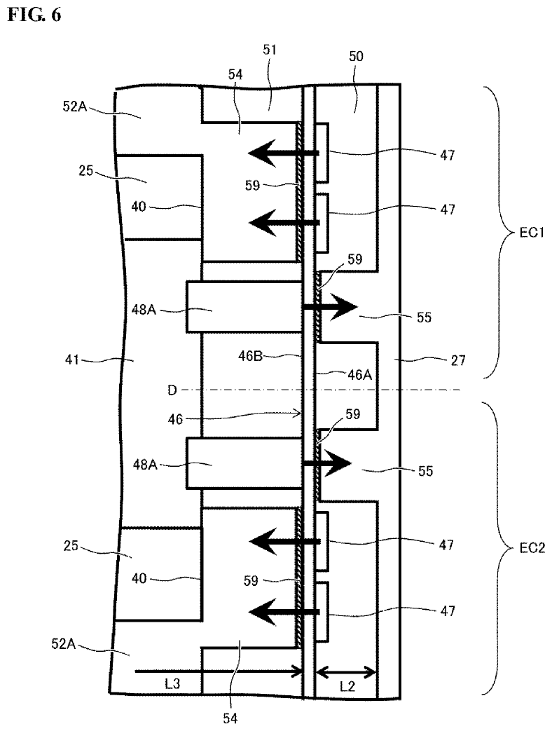

Next, the positional relationship of the mounting substrate 46 and the first, second third heat dissipation members 54, 55 and 58 will be explained in detail below with reference to FIGS. 5 and 6.

As shown in FIG. 5, the electronic controller 28 is redundantly configured with power supply circuit blocks, power conversion circuit blocks and control circuit blocks such that the first and second electronic control sections EC I and EC2 of the redundant system are located on respective both sides of a dividing line D.

The first electronic control section EC1 for driving control of the first motor coil and the second electronic control section EC2 for driving control of the second motor coil function together as the normal electronic controller. In the event of an anomaly or a failure in one of the electronic control sections, the electronic motor is driven and controlled at half power by the other electronic control section. In this case, the electric power steering function of the device is ensured even though the ability of the electric motor becomes half.

Alternatively, the redundant system may be configured to drive and control the electric motor by the first electronic control section EC1 in a normal operating state and to drive and control the electric motor by the second electronic control section EC2 in the event of an anomaly or failure in the first electronic control section EC1. Although the type of redundant system to be used is arbitrary, the former type of redundant system is used in the present embodiment.

In FIG. 5, the heat generating components of the first and second electronic control sections EC1 and EC2 on the metal cover 27 side mounting surface (first surface 46A) of the mounting substrate 46 are representatively shown. In the present embodiment, the coils 49 are not treated as the heat generating components.

More specifically, the MOSFET 47UB as the upper and lower arm component of the power conversion circuit, the MOSFET 47P as the phase relay component of the power conversion circuit and the coils 49 and MOSFET 57 as the constituent component of the power supply circuit are mounted on the metal cover 27 side mounting surface (first surface 46A) of the mounting substrate 46; and the capacitors 48A and 48B (indicated by broken lines) as the constituent components of the power supply circuit etc. are mounted on the lateral wall part 37 side mounting surface (second surface 46B) of the mounting substrate 46.

As shown in FIG. 5, the first heat dissipation member 54 is in contact with a portion of the lateral wall part 37 side mounting surface (second surface 46B) of the mounting substrate 46 corresponding to the mounted area of the MOSFET 47US and the phase relay MOSFET 47P. In other words, the first heat dissipation member 54, which dissipates heat generated by the MOSFET 47 on the metal cover 27 side mounting surface (first surface 46A) of the mounting substrate 46, is in contact with the lateral wall part 37 side mounting surface (second surface 46B) of the mounting substrate 46 at a position corresponding to the mounted position of the MOSFET 47 so as to allow heat dissipation to the controller case 52 and the motor housing 25.

On the other hand, the capacitor 48A as the constituent component of the power supply circuit and the capacitor 48B as the constituent component of the noise filter circuit are mounted on the lateral wall part 37 side mounting surface (second surface 46B) of the mounting substrate 46 as mentioned above. The second heat dissipation member 55 is in contact with a portion of the metal cover 27 side mounting surface (first surface 46A) of the mounting substrate 46 corresponding to the mounted area of the capacitors 48A and 48B. In other words, the second heat dissipation member 55, which dissipates heat generated by the capacitor 48A, 48B on the lateral wall part 37 side mounting surface (second surface 46B) of the mounting substrate 46, is in contact with the metal cover 27 side mounting surface (first surface 46A) of the mounting substrate 46 at a position corresponding to the mounted position of the capacitor 48A, 48B so as to allow heat dissipation to the metal cover 27.

In FIG. 6, a part of the electronic controller unit in the vicinity of the mounting substrate 46 is shown in cross section for the purpose of more clearly illustrating the positional relationship of the mounting substrate 46 and the heat dissipation members 54 and 55.

As mentioned above, the MOSFET 47 as the heat generating component is mounted on the metal cover 27 side mounting surface (first surface 46A) of the mounting substrate 46. This heat generating component is a short-type electronic component. The second heat dissipation member 55 is provided between the mounting substrate 46 and the metal cover 27. The length of the second heat dissipation member 55 in the axial direction is set equal to the length (L2) of the first electrical/electronic component accommodation space region 50. In this way, the length of the first heat dissipation member 54 is determined in accordance with the size of the electronic and electrical components mounted on the metal cover 27 side mounting surface (first surface 46A) of the mounting substrate 46.

The position of the area of contact of the mounting substrate 46 (first surface 46A side) with the second heat dissipation member 55 and the position of mounting of the capacitor 48A, 48B on the lateral wall part 37 side mounting surface (second surface 46B) are substantially the same in the axial direction of the rotation shaft 30.

In other words, the second heat dissipation member 55 and the mounting substrate 46 are brought into contact with each other on the side opposite to the mounted position of the capacitor 48A, 48B. Preferably, the shape of the second heat dissipation member 55 is determined in such a manner that the region of the contact area of the mounting substrate 46 (first surface 46A side) with the second heat dissipation member 55 and includes the region of the contact area of the mounting substrate 46 (second surface 46B side) with the capacitors 48 in plan view.

With such an arrangement configuration, heat generated by the capacitors 48 is transferred through the mounting substrate 46 to the second heat dissipation member 55 from the opposite side (first surface 46A side), transferred to the metal cover 27, and then, dissipated to the outside.

Further, the capacitor 48A, 48B as the heat generating component is mounted on the lateral wall part 37 side mounting surface (second surface 46B) of the mounting substrate 46 as mentioned above. This heat generating component is a tall-type electrical component. The first heat dissipation member 54 is provided between the mounting substrate 46 and the lateral wall part 37. The length of the first heat dissipation member 54 in the axial direction is set as a part of the length (L3) of the second electrical/electronic component accommodation space region 51. The length (L3) is the sum of the length of the first heat dissipation member 54 in the axial direction and the length (L1) from the open end 40 of the motor housing 25 to the lateral wall part 37. In this way, the length of the first heat dissipation member 54 is set in accordance with the size of the electronic and electrical components mounted on the lateral wall part 37 side mounting surface (second surface 46B) of the mounting substrate 46.

The position of the area of contact of the mounting surface 46 (second surface 46B side) with the first heat dissipation member 54 and the position of mounting of the MOSFET 47 on the metal cover 27 side mounting surface (first surface 46A) are substantially the same in the axial direction of the rotation shaft 30.

In other words, the first heat dissipation member 54 and the mounting substrate 46 are brought into contact with each other on the side opposite to the mounted position of the MOSFET 47. Preferably, the shape of the first heat dissipation member 54 is determined in such a manner that the region of the contact area of the mounting substrate 46 (second surface side) with the first heat dissipation member 54 includes the region of the contact area of the mounting substrate 46 (first surface side) with the MOSFET 47 in plan view.

With such an arrangement configuration, heat generated by the MOSFETs 47 is transferred through the mounting substrate 46 to the first heat dissipation member 54, transferred to the controller case 52 and the motor housing 25, and then, dissipated to the outside.

A clearance may be left at the contact area (second surface 46B side) of the mounting substrate 46 and the first heat dissipation member 54 and at the contact area (first surface 46A side) of the mounting substrate 46 and the second heat dissipation member 55 and be filled with a highly thermally conductive material having an electrical insulation property. Examples of such a thermally conductive material are a heat dissipation sheet and a heat dissipation paste. Even when the slight clearance is present at the contact area, the heat transfer efficiency can be improved by filling the clearance with the heat dissipation sheet or heat dissipation paste etc.

Herein, the amount of heat generated by the MOSFET 47 is larger than the amount of heat generated by the capacitor 48. The heat generated by the MOSFET 47 is thus transferred to the controller case 52 and the motor housing 25 because the controller case 52 and the motor housing 25 each have a large heat capacity to receive a large amount of heat and have a great heat dissipation area to enable efficient heat dissipation. Further, there occurs less thermal interference because the heat generated by the capacitor 48 is transferred to the metal cover 27 and the heat generated by the MOSFET 47 is transferred to the controller case 52 and the motor housing 25. This leads to a further improvement of heat dissipation performance.

Although the power supply circuit, the power conversion circuit and the control circuit are mounted on both sides of one mounting substrate in the above-mentioned embodiment, the present invention is not limited to this structure. One or more of the above-mentioned circuits can be mounted on both sides of one mounting substrate. Needless to say, the present invention is applicable to such a modification example.

As described above, the electronic controller of the present invention is so configured that: the first heat generating component is mounted on the first surface on one side of the mounting substrate; the second heat generating component is mounted on the second surface on the other side of the mounting substrate; the first heat dissipation member, which dissipates heat generated by the first heat generating component mounted on the first surface, is in contact with the second surface at a position corresponding to the mounted position of the first heat generating component so as to allow heat dissipation to the motor housing; and the second heat dissipation member, which dissipates heat generated by the second heat generating component mounted on the second surface, is in contact with the first surface at a position corresponding to the mounted position of the second heat generating component so as to allow heat dissipation to the cover.

The heat of the first heat generating component mounted on the cover-side first surface is dissipated to the motor housing through the first heat dissipation member which is arranged in contact with the second surface opposite to the cover side; and the heat of the second heat generating component mounted on the second surface opposite to the cover side is dissipated to the cover through the second heat dissipation member arranged in contact with the cover-side first surface. The cover and the cover-side heat generating component are thus kept from contact with each other. This makes it possible to not only prevent damage on the cover-side heat generating component but also efficiently dissipate the heat of the heat generating components to the outside.

It should be understood that the present invention is not limited to the above-mentioned embodiment. Various changes and modifications of the above-mentioned embodiment are included in the scope of the present invention. The above-mentioned embodiment has been described in detail for the purpose of clearly understandably explaining the present invention. The present invention is not necessarily limited to those having all of the above-mentioned features. It is feasible to replace any of the structural features of one embodiment with those of the other embodiment or feasible to add any of the structural features of one embodiment to the other embodiment. One embodiment can be implemented by adding, deleting or replacing any of the structural features of the other embodiment.

Although the above-mentioned embodiment refers to the electronic power steering device for imparting a steering assist force to assist the steering force caused by driver's steering wheel operation, the present invention is applicable to an electric steering device capable of performing a steering function by automatically generating a steering force by means of an electric motor as a drive source in a state that there is no driver's steering operation or a steering device having an automatic steering function.

1. An electric drive device, comprising:
a highly thermally conductive motor housing that accommodates therein an electric motor for driving a mechanical control element;
a highly thermally conductive cover disposed on an end side of the motor housing opposite to an output portion of a rotation shaft of the electric motor; and
an electronic controller accommodated in an accommodation space defined by the cover and provided with control components for driving the electric motor,
wherein the electronic controller comprises:
a mounting substrate having one surface defined as a first surface and the other surface defined as a second surface, the control components including a first heat generating component having a heat generating attribute and mounted on the first surface and a second heat generating component having a heat generating attribute and mounted on the second surface;
a first heat dissipation member that dissipates heat generated by the first heat generating component mounted on the first surface, the first heat dissipation member being in contact with the second surface at a position corresponding to a mounted position of the first heat generating component such that the heat generated by the first heat generating component is dissipated to the motor housing through the first heat dissipation member; and
a second heat dissipation member that dissipates heat generated by the second heat generating component mounted on the second surface, the second heat dissipation member being in contact with the first surface at a position corresponding to a mounted position of the second heat generating component such that the heat generated by the second heat generating component is dissipated to the cover through the second heat dissipation member.

2. The electric drive device a(iorctl comprising:
a highly thermally conductive controller case disposed between the motor housing and the cover;
wherein the electronic controller is accommodated in the ccommodation space defined by the cover, the controller case and the end side of the motor housing;
wherein the first heat dissipation member is in contact with the second surface at a position corresponding to a mounted position of the first heat generating component such that the heat generated by the first heat generating component is dissipated to the controller case and the motor housing through the first heat dissipation member; and
wherein the second heat dissipation member is in contact with the first surface at a position corresponding to a mounted position of the second heat generating component such that the heat generated by the second heat generating component is dissipated to the cover through the second heat dissipation member.

3. The electric drive device according to claim 2,
wherein the first heat dissipation member is formed of a metal material integrally with the controller case and is thermally coupled to the end side of the motor housing; and
wherein the second heat dissipation member is formed of a metal material integrally with the cover.

4. The electric drive device according to claim 1,
wherein each of the motor housing, the cover, the first heat dissipation member and the second heat dissipation member is formed of a metal material;
wherein the mounting substrate is arranged in the accommodation space such that the accommodation space is divided into a first accommodation space region between the cover and the first surface of the mounting substrate and a second accommodation space region between the end side of the motor housing and the second surface of the mounting substrate;
wherein the second heat dissipation member is located in the first accommodation space region and is thermally coupled to the cover; and
wherein the first heat dissipation member is located in the second accommodation space region and is thermally coupled to the motor housing.

5. The electric drive device according to claim 4,
wherein a relationship of L2<L3 is satisfied where L2 is a length of the first accommodation space region between the cover and the first surface of the mounting substrate, and L3 is a length of the second accommodation space region between the end side of the motor housing and the second surface of the mounting substrate.

6. The electric drive device according to claim 5,
wherein the first heat generating component mounted on the first surface of the mounting substrate has a height from the mounting substrate, which is smaller than the length L2 of the first accommodation space region; and
wherein the second heat generating component mounted on the second surface of the mounting substrate has a height from the from the mounting substrate, which is greater than the length L2 of the first accommodation space region and smaller than the length L3 of the second accommodation space region.

7. The electric drive device according to claim 6,
wherein the first heat generating component is a power switching element; and
wherein the second heat generating component is a capacitor.

8. The electric drive device according to claim 4,
wherein the first heat dissipation member is shaped such that a region of a contact area of the second surface of the mounting substrate with the first heat dissipation member includes a region of a contact area of the first surface of the mounting substrate with the first heat generating component; and
wherein the second heat dissipation member is shaped such that a region of a contact area of the first surface of the mounting substrate with the second heat dissipation member includes a region of a contact area of the second surface of the mounting substrate with the second heat generating component.

9. The electric drive device according to claim 4,
wherein the electronic controller has a redundant system constituted by first and second electronic control sections;
wherein the first heat generating component is provided in each of the first and second electronic control sections by being mounted on the first surface of the mounting substrate,
wherein the second heat generating component is provided in each of the first and second electronic control sections by being mounted on the second surface of the mounting substrate;
wherein the second heat dissipation member is provided, corresponding to the second heat generating component of each of the first and second electronic control sections, in the first accommodation space region and is thermally coupled to the cover; and
wherein the first heat dissipation member is provided, corresponding to the first heat generating component of each of the first and second electronic control sections, in the second accommodation space region and is thermally coupled to the motor housing.

10. An electric steering device, comprising:
an electric motor that imparts a steering force to a steering shaft;
a thermally conductive motor housing that accommodates therein the electric motor;
a thermally conductive cover disposed on an end side of the motor housing opposite to an output portion of a rotation shaft of the electric motor; and
an electronic controller accommodated in an accommodation space defined by the cover and provided with control components for driving the electric motor,
wherein the electronic controller comprises:
a mounting substrate having one surface defined as a first surface and the other surface defined as a second surface, the control components including a first heat generating component having a heat generating attribute and mounted on the first surface and a second heat generating component having a heat generating attribute and mounted on the second surface;
a first heat dissipation member that dissipates heat generated by the first heat generating component mounted on the first surface, the first heat dissipation member being in contact with the second surface at a position corresponding to a mounted position of the first heat generating component such that the heat generated by the first heat generating component is dissipated to the motor housing through the first heat dissipation member; and
a second heat dissipation member that dissipates heat generated by the second heat generating component mounted on the second surface, the second heat dissipation member being in contact with the first surface at a position corresponding to a mounted position of the second heat generating component such that the heat generated by the second heat generating component is dissipated to the cover through the second heat dissipation member.

11. The electric steering device according to claim 10, further comprising:
a highly thermally conductive controller case disposed between the motor housing and the cover;
wherein the electronic controllers accommodated in the accommodation space defined by the cover, the controller case and the end side of the motor housing;
wherein the first heat dissipation member is in contact with the second surface at a position corresponding to a mounted position of the first heat generating component such that the heat generated by the first heat generating component is dissipated to the controller case and the motor housing through the first heat dissipation member; and
wherein the second heat dissipation member is in contact with the first surface at a position corresponding to a mounted position of the second heat generating component such that the heat generated by the second heat generating component is dissipated to the cover through the second heat dissipation member.

12. The electric steering device according to claim 10,
wherein a torque sensor is arranged to detect a rotation direction and rotation torque of the steering shaft caused by driver's steering operation and produce an output according to the detected rotation direction and rotation torque; and
wherein the electric motor exerts a steering assist force on the steering shaft based on the output of the torque sensor.

13. An electric drive device, comprising:
a mounting substrate located on a side of an electric motor opposite to an output portion of a rotation shaft of the electric motor, the electric motor being arranged to drive a mechanical control element, the mounting substrate having a component mounting surface facing in an axial direction of the electric motor and adapted to mount thereon electronic components, the component mounting surface including a first component mounting surface directed opposite to the electric motor and a second component mounting surface directed toward the electric motor;
a thermally conductive first exterior member at least partially facing the first component mounting surface;
a thermally conductive second exterior member at least partially facing the second component mounting surface;
a first heat generating component having a heat generating attribute and mounted, as one of the electronic components, on the first component mounting surface;
a second heat generating component having a heat generating attribute and mounted, as one of the electronic components, on the second component mounting surface; and
first and second heat dissipation members that allow heat transfer from the mounting substrate to the first and second exterior members, respectively, in a state that the mounting substrate is accommodated in an inner accommodation space defined by the first and second exterior members,
wherein the first heat dissipation member is arranged facing and opposed to a portion of the second component mounting surface corresponding to a mounted position of the first heat generating component; and
wherein the second heat dissipation member is arranged facing and opposed to a portion of the first component mounting surface corresponding to a mounted position of the second heat generating component.

14. An electric steering device, comprising:
an electric motor that exerts a steering assist force on a steering shaft based on an output of a torque sensor which is arranged to detect a rotation direction and rotation torque of the steering shaft and produce the output according to the detected rotation direction and rotation torque;
a highly thermally conductive motor housing that accommodates therein the electric motor;
a highly thermally conductive cover disposed on an end side of the motor housing opposite to an output portion of a rotation shaft of the electric motor; and
an electronic controller accommodated in an accommodation space defined by the cover and provided with control components for driving the electric motor,
wherein the electronic controller comprises:
a mounting substrate having one surface defined as a first surface and the other surface defined as a second surface, the control components including a first heat generating component having a heat generating attribute and mounted on the first surface and a second heat generating component having a heat generating attribute and mounted on the second surface;
a first heat dissipation member that dissipates heat generated by the first heat generating component mounted on the first surface, the first heat dissipation member being in contact with the second surface at a position corresponding to a mounted position of the first heat generating component such that the heat generated by the first heat generating component is dissipated to the motor housing through the first heat dissipation member; and
a second heat dissipation member that dissipates heat generated by the second heat generating component mounted on the second surface, the second heat dissipation member being in contact with the first surface at a position corresponding to a mounted position of the second heat generating component such that the heat generated by the second heat generating component is dissipated to the cover through the second heat dissipation member.

15. The electric steering device according to claim 14, further comprising:
a highly thermally conductive controller case disposed between the motor housing and the cover;
wherein the electronic controllers accommodated in the accommodation space defined by the cover, the controller case and the end side of the motor housing;
wherein the first heat dissipation member is in contact with the second surface at a position corresponding to a mounted position of the first heat generating component such that the heat generated by the first heat generating component is dissipated to the controller case and the motor housing through the first heat dissipation member; and
wherein the second heat dissipation member is in contact with the first surface at a position corresponding to a mounted position of the second heat generating component such that the heat generated by the second heat generating component is dissipated to the cover through the second heat dissipation member.

16. The electric steering device according to claim 15,
wherein the first heat dissipation member is formed of a metal material integrally with the controller case and is thermally coupled to the end side of the motor housing; and
wherein the second heat dissipation member is formed of a metal material integrally with the cover.

17. The electric steering device according to claim 14,
wherein each of the motor housing, the cover, the first heat dissipation member and the second heat dissipation member is formed of a metal material;
wherein the mounting substrate is arranged in the accommodation space such that the accommodation space is divided into a first accommodation space region between the cover and the first surface of the mounting substrate and a second accommodation space region between the end side of the motor housing and the second surface of the mounting substrate;
wherein the second heat dissipation member is located in the first accommodation space region and is thermally coupled to the cover; and
wherein the first heat dissipation member is located in the second accommodation space region and is thermally coupled to the motor housing.

18. The electric steering device according to claim 17,
wherein a relationship of L2<L3 is satisfied where L2 is a length of the first accommodation space region between the cover and the first surface of the mounting substrate, and L3 is a length of the second accommodation space region between the end side of the motor housing and the second surface of the mounting substrate.

19. The electric steering device according to claim 18,
wherein the first heat generating component mounted on the first surface of the mounting substrate has a height from the mounting substrate, which is smaller than the length L2 of the first accommodation space region; and
wherein the second heat generating component mounted on the second surface of the mounting substrate has a height from the from the mounting substrate, which is greater than the length L2 of the first accommodation space region and smaller than the length L3 of the second accommodation space region.

20. The electric steering device according to claim 19,
wherein the first heat generating component is a power switching element, and
wherein the second heat generating component is a capacitor.

21. The electric steering device according to claim 17,
wherein the first heat dissipation member is shaped such that a region of a contact area of the second surface of the mounting substrate with the first heat dissipation member includes a region of a contact area of the first surface of the mounting substrate with the first heat generating component; and
wherein the second heat dissipation member is shaped such that a region of a contact area of the first surface of the mounting substrate with the second heat dissipation member includes a region of a contact area of the second surface of the mounting substrate with the second heat generating component.

22. The electric steering device according to claim 17,
wherein the electronic controller has a redundant system constituted by first and second electronic control sections;
wherein the first heat generating component is provided in each of the first and second electronic control sections by being mounted on the first surface of the mounting substrate;
wherein the second heat generating component is provided in each of the first and second electronic control sections by being mounted on the second surface of the mounting substrate;
wherein the second heat dissipation member is provided, corresponding to the second heat generating component of each of the first and second electronic control sections, in the first accommodation space region and is thermally coupled to the cover; and
wherein the first heat dissipation member is provided, corresponding to the first heat generating component of each of the first and second electronic control sections, in the second accommodation space region and is thermally coupled to the motor housing.
